(19) United States
(12) Patent Application Publication
(10) Pub. No.: US 2025/0051902 A1
(43) Pub. Date: Feb. 13, 2025

(54) METHODS OF FORMING CONFORMAL TRANSITION METAL DICHALCOGENIDE FILMS

(71) Applicant: Applied Materials, Inc., Santa Clara, CA (US)

(72) Inventors: Chandan Das, Singapore (SG); Bencherki Mebarki, Santa Clara, CA (US); Jiecong Tang, Singapore (SG); Mohammed Mahdi Tavakoli, Sunnyvale, CA (US); John Sudijono, Singapore (SG); Joung Joo Lee, San Jose, CA (US)

(73) Assignee: Applied Materials, Inc., Santa Clara, CA (US)

(21) Appl. No.: 18/232,631

(22) Filed: Aug. 10, 2023

(51) Int. Cl. C23C 12/00; C23C 16/40; C23C 16/455; C23C 16/56

(52) U.S. Cl. CPC C23C 12/00; C23C 16/405; C23C 16/45536; C23C 16/56

(57) ABSTRACT

Transition metal dichalcogenide (TMDC) films and methods for conformally depositing TMDC films on a substrate surface are described. The substrate surface may have one or more features formed therein, one or more layers formed thereon, and combinations thereof. The substrate surface is exposed to a transition metal precursor and an oxidant to form a transition metal oxide film in a first phase. The transition metal oxide film is exposed to a chalcogenide precursor to convert the transition metal oxide film to the TMDC film in a second phase.

### TECHNICAL FIELD

Embodiments of the disclosure generally relate to methods of forming transition metal dichalcogenide (TMDC) films. More particularly, embodiments of the disclosure are directed to methods of forming TMDC films for high aspect ratio structures and for barrier and liner material applications in back-end-of-line (BEOL) processes.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deposit precursor molecules on a substrate surface in sequential cycles. The cycles include exposing the substrate surface to a first precursor, a purge gas, a second precursor, and the purge gas. The first and second precursors react to form a product compound as a film on the substrate surface. The cycles may be repeated to form the layer to a desired thickness.

The advancing complexity of advanced microelectronic devices is placing stringent demands on currently used deposition techniques. Unfortunately, there is a limited number of viable chemical precursors and processes to provide films with suitable crystallinity, grain size, continuity, and electrical conductivity.

Transition metal dichalcogenides (TMDCs) are known to be great candidates to mitigate the issue of metal migration associated with interconnect downscaling of films. Moreover, TMDCs possess better conductivity and carrier mobility compared to current processes in 3D-NAND devices. Typical TMDC deposition methods require high temperature processes which may not be compatible with device thermal budgets.

Accordingly, there is a need for improved TMDC deposition methods that can conformally grow TMDC films by low temperature thermal processes suitable for device integration in temperature sensitive structures.

### SUMMARY

One or more embodiments of the disclosure are directed to a method of forming a transition metal dichalcogenide film. The method comprises depositing a transition metal oxide film on a semiconductor substrate surface by sequentially exposing the semiconductor substrate surface to a transition metal precursor and an oxidant, the oxidant comprising one or more of an alcohol or deionized/deoxygenated water; and converting the transition metal oxide film to the transition metal dichalcogenide film.

Additional embodiments of the disclosure are directed to a method of forming a transition metal dichalcogenide film on a semiconductor substrate surface comprising at least one feature. The method comprises sequentially exposing the semiconductor substrate surface to a transition metal precursor and an oxidant to directly deposit a transition metal oxide film without forming a transition metal film intermediate. The transition metal precursor comprises one or more of bis(t-butylimino) bis(dimethylamino) tungsten(VI), bis(isopropylcyclopentadienyl) tungsten(IV) dihydride, bis(cyclopentadienyl) tungsten dihydride, bis(t-butylimino) bis(dimethylamino) molybdenum(VI), pentakis (dimethylamino) tantalum (V), or tetrakis (dimethylamido) titanium (IV). The oxidant comprises one or more of an alcohol or deionized/deoxygenated water. The method further comprises exposing the transition metal oxide film to a chalcogenide precursor to convert the transition metal oxide film to the transition metal dichalcogenide film. The semiconductor substrate surface is maintained at a temperature in a range of about 150° C. to about 450° C. In some embodiments, converting the transition metal oxide film is performed at a pressure in a range of from 0.1 Torr to 100 Torr.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

The embodiments as described herein are illustrated by way of example and not limitation in the figures of the accompanying drawings in which like references indicate similar elements.

FIG. 1 illustrates a process flow diagram of a method in accordance with one or more embodiments of the disclosure;

FIG. 2 illustrates a cross-sectional view of a semiconductor substrate in accordance with one or more embodiments of the disclosure; and

FIG. 3 illustrates a cross-sectional view of a semiconductor substrate in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” may include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used herein, the terms “substrate surface” or “semiconductor substrate surface” may be interchangeably used to refer to any substrate surface upon which a layer may be formed. The substrate (or substrate surface) may be pretreated prior to the disclosed methods, for example, by polishing, etching, reduction, oxidation, halogenation, hydroxylation, annealing, baking, or the like.

The semiconductor substrate surface may have one or more features formed therein, one or more layers formed thereon, and combinations thereof. The feature may define any suitable shape including, but not limited to, peaks, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 5:1, 10:1, 15:1, 20:1, 25:1, 30:1, 35:1, or 40:1.

According to one or more embodiment, the term “on”, with respect to a film or a layer of a film, includes the film or layer being directly on a surface, for example, a semiconductor substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is only substantially exposed to one reactive compound at a time. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface.

In some embodiments, the ALD process of pulsing compound A, purge gas, compound B and purge gas is a cycle. A cycle can start with either compound A or compound B and continue the respective order of the cycle until achieving a film with the desired thickness. In some embodiments, there may be two reactants, A and B, that are alternatingly pulsed and purged.

In some embodiments, there may be three or more reactants, A, B, and C, that are alternatingly pulsed and purged. In some embodiments, each reactant is utilized during each deposition cycle (e.g., A-B-C). In some embodiments, a series of alternating exposures to compounds A and B may be performed before exposure to compound C (e.g., A-B-A-B-C).

In a spatial ALD process, a first reactive gas and a second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

According to one or more embodiments, the disclosed method utilize an atomic layer deposition (ALD) process. In such embodiments, the substrate surface is exposed to the precursors (or reactive gases) sequentially. As used herein, throughout the specification, “sequentially” means that the duration of a precursor exposure does not intentionally overlap with the exposure to a reactant in a manner intended to create a gas phase reaction. It is understood that while some overlap may occur, this overlap is unintentional.

Embodiments of the disclosure advantageously provide a pathway to grow TMDC films at lower temperatures, such as in a range of from about 150° C. to about 500° C., or in a range of from about 150° C. to about 450° C., which is suitable for device integration in temperature sensitive structures and devices. Embodiments of the disclosure provide methods of forming high-quality TMDC films in terms of crystallinity, grain size, continuity, and electrical conductivity for use as a channel material, liner, or barrier layer in the miniaturization and scaling of integrated circuits. Embodiments of the disclosure provide methods of forming high-quality 2D-TMDC films for temperature-sensitive device architectures.

Embodiments of the disclosure advantageously provide conformally deposited crystalline TMDC films which can be used in memory and logic applications, such as, for example, barrier and liner material applications in back-end-of-line (BEOL) processes. For example, the TMDC film acting as a barrier/liner may enable nucleation of a subsequently deposited metal, adhesively bind a metal to underlying dielectric materials, and block diffusion of metal elements to underlying dielectric materials. The TMDC films can advantageously be used in high aspect ratio structures.

Some embodiments provide methods of forming TMDC films by thermal or plasma-based processes.

Embodiments of the disclosure advantageously provide methods of forming TMDC films via a low energy barrier pathway. In some embodiments, in the low energy barrier pathway, the transition metal precursors are used in their various forms (metal, metal oxide, metal chloride, metal oxychloride, and the like). In one or more embodiments, the methods include depositing an ultrathin layer to a few nm thick, followed by oxidation, then exposure to a chalcogenide precursor, (e.g., sulfurization), which forms high-quality TMDC films. Advantageously, the methods described herein provide a low energy barrier pathway for sulfurization of transition metals or their precursors to metal sulfides. Based on this low energy barrier pathway, the methods advantageously form a conformal and continuous TMDC film, such as a WS₂ film, in all regions of a high aspect ratio structure, such as a trench.

The embodiments of the disclosure are described by way of the Figures, which illustrate processes and substrates in accordance with one or more embodiments of the disclosure. The processes, schemes, and resulting substrates shown are merely illustrative of the disclosed processes, and the skilled artisan will recognize that the disclosed processes are not limited to the illustrated applications.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

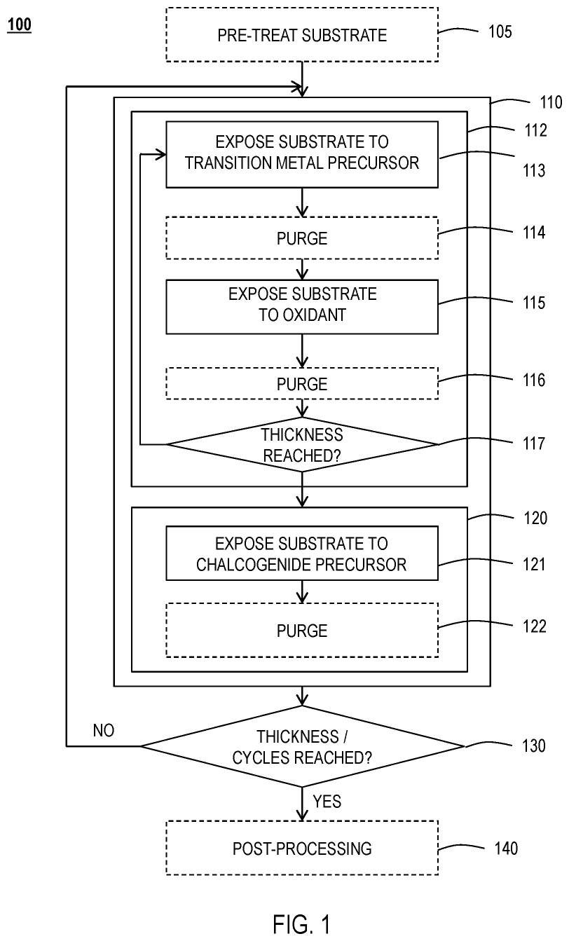

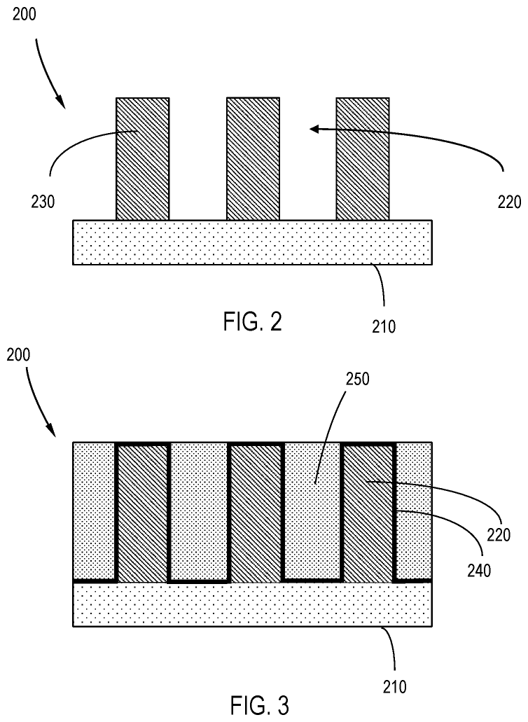

FIG. 1 illustrates a process flow diagram of a method 100 of forming a transition metal dichalcogenide film. FIGS. 2 and 3 illustrate cross-sectional views of a semiconductor substrate 200 in accordance with one or more embodiments of the disclosure. The method 100 can be used to form a transition metal dichalcogenide film on a substrate, such as, for example, the semiconductor substrate 200 shown in FIGS. 2 and 3.

The method 100 illustrated in FIG. 1 is representative of an atomic layer deposition (ALD) process in which the semiconductor substrate or semiconductor substrate surface is exposed sequentially to the reactive gases in a manner that prevents or minimizes gas phase reactions of the reactive gases. In so doing, the method 100 advantageously avoids a chemical vapor deposition (CVD) process in which the reactive gases are mixed in the processing chamber to allow gas phase reactions of the reactive gases.

In one or more embodiments, the method 100 comprises optionally pre-treating the substrate at operation 105. A transition metal dichalcogenide film is formed on the substrate in a deposition process cycle 110. The deposition process cycle 110 can be understood in two phases 112, 120. A first phase 112 comprising operations 113, 114, 115, 116, and decision 117, forms a transition metal oxide film on the substrate surface. In the first phase 112, the transition metal oxide film is directly formed without forming a transition metal film intermediate. A second phase 120 comprising operations 121 and 122 converts the transition metal oxide film formed in the first phase 112 to a transition metal dichalcogenide film.

In some embodiments, the second phase 120 is performed after the first phase 112 has deposited the transition metal oxide film to a predetermined thickness. In some embodiments, the second phase 120 is performed after a single cycle of the first phase 112. In some embodiments, the second phase 120 is performed after multiple cycles of the first phase 112.

The first phase 112 comprises sequentially exposing the substrate to a transition metal precursor at operation 113, optionally purging the substrate surface at operation 114, exposing the substrate to an oxidant at operation 115, and optionally purging the substrate surface at operation 116 to deposit the transition metal oxide film.

The second phase 120 comprises sequentially exposing the substrate to a chalcogenide precursor at operation 121 and, optionally, purging the substrate surface at operation 122 to convert the transition metal oxide film to the transition metal dichalcogenide film.

In some embodiments, the method 100 optionally includes a pre-treatment operation 105. In one or more embodiments, method 100 includes pre-treating the substrate surface at operation 105 prior to depositing the transition metal oxide film (first phase 112). The pre-treatment can be any suitable pre-treatment process known to the skilled artisan. Suitable pre-treatments include, but are not limited to, pre-heating, cleaning, soaking, native oxide removal, or the like.

It has been observed that the substrate surface, such as, for example, a low-κ dielectric substrate surface, is sensitive to strong oxidants while growing the transition metal oxide film in the first phase 112. It remains a challenge for the transition metal precursors to adsorb on inherently highly hydrophobic alkyl-group terminated dielectric surfaces. In some embodiments, the method 100 comprises pre-treating the substrate surface at operation 105 with a plasma treatment or ultraviolet (UV) radiation exposure to remove surface alkyl groups and make the low-K dielectric surface suitable for precursor adsorption. Advantageously, the oxidant comprising one or more of an alcohol or deionized/deoxygenated water does not damage the low-K dielectric surface. Additionally, use of the transition metal precursors and the oxidant comprising one or more of an alcohol or deionized/deoxygenated water advantageously enables uniform growth of the transition metal oxide film without modifying the properties of, or damaging, the low-κ dielectric surface.

In one or more embodiments, the plasma treatment of operation 105 comprises exposing the substrate surface to a plasma of carbon dioxide (CO₂). In one or more embodiments, the plasma of CO₂ further comprises an inert gas, including, but not limited to, argon (Ar), helium (He), or nitrogen (N₂). In one or more embodiments, the substrate surface is exposed to the plasma of CO₂ for a time period in a range of from about 0.5 seconds to about 20 seconds.

Without intending to be bound by theory, it is thought that the κ-value of the low-κ dielectric substrate surface, such as silicon oxycarbide (SiOC), is dependent on the oxidant used during the method 100. It has been advantageously found that the oxidant described herein does not change the κ-value and is suitable for deposition on a low-κ dielectric substrate surface.

In one or more embodiments, the stoichiometry of the TMDC film was measured by x-ray photoelectron spectroscopy (XPS). In one or more embodiments, a TMDC film comprising WS₂ and having a stoichiometric ratio of sulfur:tungsten in a range of from 1:1 to 1:2 with impurities, e.g., carbon (C), nitrogen (N₂), and/or oxygen (O₂), such as about 5% nitrogen (N₂), does not change the κ-value and is suitable for deposition on a low-κ dielectric substrate surface.

In specific embodiments, it has advantageously been found that exposing the substrate surface to the plasma of CO₂ for a time period in a range of from about 0.5 seconds to about 20 seconds does not modify the properties of, or damage, the substrate surface, such as a low-κ dielectric surface, where there is no change in κ-value.

In one or more embodiments, the pre-treatment of operation 105 comprises exposing the substrate surface to ultraviolet (UV) radiation. In one or more embodiments, the pre-treatment of operation 105 comprises exposing the substrate surface to UV radiation for a time period in a range of from about 0.5 seconds to about 30 seconds. In one or more embodiments, exposing the substrate surface to UV radiation includes using a UV lamp that generates the UV radiation.

In one or more embodiments, the method 100 comprises, consists essentially of, or consists of pre-treating the substrate (operation 105), deposition process cycle 110 including the first phase 112 [comprising sequentially exposing the substrate to a transition metal precursor at operation 113, purging the substrate surface at operation 114, exposing the substrate to an oxidant at operation 115, and purging the substrate surface at operation 116 to deposit the transition metal oxide film], the second phase [comprising sequentially exposing the substrate to a chalcogenide precursor at operation 121 and purging the substrate surface at operation 122 to convert the transition metal oxide film (formed in the first phase 112) to the transition metal dichalcogenide film].

In the first phase 112 of the deposition process cycle 110, in one or more embodiments, at operation 113, the substrate (or substrate surface) is exposed to a transition metal precursor to form a reactive metal species on the substrate surface. The transition metal precursor can be any suitable transition metal containing compound that can react (i.e., adsorb or chemisorb onto) the substrate surface to leave a transition metal containing species on the substrate surface. It is thought that any transition metal containing compound, which, based on its size, can inhibit diffusion through pores in the substrate surface, where each pore has a size in a range of from 5 Å to 20 Å, is suitable.

In one or more embodiments, the transition metal precursor does not comprise oxygen or halogen atoms. In some embodiments, the transition metal precursor does not comprise, consist essentially of, or consist of oxygen or halogen atoms.

In one or more embodiments, the transition metal precursor comprises one or more of tungsten (W), molybdenum (Mo), tantalum (Ta), titanium (Ti), or ruthenium (Ru).

In one or more embodiments, the transition metal precursor comprises, consists essentially of, or consists of one or more of bis(t-butylimino) bis(dimethylamino) tungsten(VI), bis(isopropylcyclopentadienyl) tungsten(IV) dihydride, bis(cyclopentadienyl) tungsten dihydride, bis(t-butylimino) bis(dimethylamino) molybdenum(VI), pentakis (dimethylamino) tantalum (V), or tetrakis (dimethylamido) titanium (IV).

At operation 114, the processing chamber or substrate surface is optionally purged to remove unreacted transition metal precursor, reaction products, and byproducts. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the transition metal precursor by any suitable technique including, but not limited to, moving the substrate through a gas curtain to a portion or sector of the processing chamber that contains none or substantially none of the transition metal precursor.

In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

The descriptors of the purge operations described herein, both in operation and composition, may apply to any of the purge operations of the method 100: operation 114, 116, and 122.

At operation 115, the substrate (or substrate surface) is exposed to an oxidant to form a transition metal oxide film on the substrate. The oxidant (which may also be referred to as an oxide reactant) may be any suitable compound for oxidizing the adsorbed transition metal precursor to form a transition metal oxide film. As described herein, it has been observed that the substrate surface, such as, for example, a low-κ dielectric substrate surface, is sensitive to strong oxidants while growing the transition metal oxide film in the first phase 112. It remains a challenge for the transition metal precursors to adsorb on inherently highly hydrophobic alkyl-group terminated dielectric surfaces. In some embodiments, pre-treating the substrate surface at operation 105 comprises a plasma treatment or ultraviolet (UV) radiation exposure to remove surface alkyl groups and make the low-κ dielectric surface suitable for precursor adsorption.

Advantageously, the oxidant comprising one or more of an alcohol or deionized/deoxygenated water does not damage the low-κ dielectric surface. In some embodiments, the oxidant does not comprise a plasma, which, without intending to be bound by any particular theory, is also thought to damage the low-κ dielectric surface.

The alcohol can be any suitable alcohol. In one or more embodiments, the alcohol used for the oxidant comprises one or more of methanol, ethanol or isopropyl alcohol. In one or more embodiments, the alcohol used for the oxidant comprises isopropyl alcohol.

As used herein, “deionized/deoxygenated water” includes any water composition in which dissolved oxygen (DO) has been removed. In embodiments where the oxidant comprises deionized/deoxygenated water, DO can be removed by any suitable process known to the skilled artisan, and it is to be understood that the disclosure is not limited to any specific process.

At operation 116, the processing chamber or substrate surface is optionally purged to remove unreacted oxidant, reaction products, and byproducts. The purge process of operation 116 may be the same purge process or a different purge process as operation 114.

In one or more embodiments, the first phase 112 includes exposing the substrate surface to the transition metal precursor (operation 113), the purge gas (operation 114), the oxidant (operation 115), and the purge gas (operation 116). The transition metal precursor and the oxidant react to form a product compound as a film, such as the transition metal oxide film, on the substrate surface. The first phase 112 may be repeated to form the transition metal oxide film to a desired thickness (decision 117).

In one or more embodiments, the transition metal oxide film is formed to a thickness in a range of 5 Å to 50 Å, in a range of 5 Å to 35 Å, in a range of 5 Å to 25 Å, or in a range of 5 Å to 10 Å. In accordance with decision 117, the first phase 112, e.g., exposing the substrate surface to the transition metal precursor (operation 113), the purge gas (operation 114), the oxidant (operation 115), and the purge gas (operation 116), may be repeated until the transition metal oxide film is formed to the desired thickness.

The inventors have advantageously found that purging the processing chamber at operation 116 enhances the adsorption of the transition metal precursor if returning to the beginning of the first phase 112 to deposit additional transition metal oxide film. Without being bound by theory, it is believed that the purge at operation 116 provides a “clean” substrate surface, which enhances the adsorption of the transition metal precursor in operation 113.

In some embodiments, the transition metal oxide film formed in the first phase 112 is directly formed without forming a transition metal film intermediate. The inventors have surprisingly found that the formation of certain metals (e.g., tungsten) on dielectric surfaces is more difficult (e.g., longer processing times, elevated temperatures) than the formation of metal oxides. Further, the formation of a metal layer which is subsequently oxidized requires more processing time and decreases processing throughput. Accordingly, embodiments of the disclosure advantageously provide methods of forming a transition metal oxide film without the formation of a metal film intermediate.

In some embodiments, the substrate surface does not include a barrier layer. Without being bound by theory, it is believed that the formation of a metal layer without a barrier layer leads to the possible diffusion of the metal into the underlying material(s). The inventors have surprisingly found that diffusion from metal oxide materials is significantly lower. In some embodiments, the diffusion of metal atoms from metal oxide materials is low enough that the benefits of a barrier layer are negligible. Accordingly, the elimination of the barrier layer from a process flow is expected to decreasing processing time, increase throughput, and decrease resistance of the metal fill since the fill will be larger in volume. Additionally, it is thought that any transition metal containing compound, which, based on its size, can inhibit diffusion through pores in the substrate surface, where each pore has a size in a range of from 5 Å to 20 Å, is suitable as the transition metal precursor.

Once the first phase 112 is completed, and the transition metal oxide film has reached a predetermined thickness or a predetermined number of process cycles have been performed, the method 100 moves to the second phase 120.

In the second phase 120, the transition metal oxide film formed in the first phase 112 is converted to a transition metal dichalcogenide (TMDC) film. In some embodiments, converting the transition metal oxide film comprises exposing the transition metal oxide film to a chalcogenide precursor at operation 121. The chalcogenide precursor comprises one of more of sulfur (S), selenium (Se), tellurium (Te), polonium (Po), or livermorium (Lv). In some embodiments, the chalcogenide precursor comprises one of more of sulfur (S), selenium (Se), tellurium (Te). In some embodiments, the chalcogenide precursor comprises H₂S. In some embodiments, the chalcogenide precursor further comprises an inert gas, including, but not limited to, argon (Ar), helium (He), or nitrogen (N₂). In some embodiments, the chalcogenide precursor further comprises hydrogen (H₂). In some embodiments, the chalcogenide precursor does not comprise a plasma.

In one or more embodiments, the transition metal oxide film is exposed to a chalcogenide precursor comprising thermal Ar/H₂S or H₂/H₂S gas. In one or more embodiments, the transition metal oxide film is exposed to a chalcogenide precursor comprising a plasma formed from Ar/H₂S or H₂/H₂S gas. In one or more embodiments, the transition metal oxide film comprising tungsten (W) is converted to WS₂ by exposing the substrate surface to the chalcogenide precursor. In one or more embodiments, the transition metal oxide film comprising molybdenum (Mo) is converted to MoS₂ by exposing the substrate surface to the chalcogenide precursor.

In one or more embodiments, converting the transition metal oxide film to the TMDC film is conducted at a plasma power in a range of from 25 watts (W) to 500 watts (W).

In one or more embodiments, converting the transition metal oxide film to the transition metal dichalcogenide film is conducted at a temperature in a range of from about 150° C. to about 500° C., in a range of from about 150° C. to about 450° C., or in a range of from about 300° C. to about 450° C.

In some embodiments, converting the transition metal oxide film to the transition metal dichalcogenide film is performed at a pressure in a range of from 0.1 Torr to 100 Torr. In some embodiments, converting the transition metal oxide film to the transition metal dichalcogenide film is performed at a pressure in a range of from, for example, 1 Torr to 100 Torr, in a range of from 1 Torr to 50 Torr, in a range of from 1 Torr to 30 Torr, or in a range of from 1 Torr to 10 Torr. In some embodiments, the transition metal oxide film is exposed to a chalcogenide precursor comprising thermal or plasma Ar/H₂S or H₂/H₂S gas in a range of from 1 Torr to 100 Torr.

In one or more embodiments, converting the transition metal oxide film to the transition metal dichalcogenide film is conducted for a time period in a range of from 1 minute to 60 minutes.

In one or more embodiments, the TMDC film is substantially free of oxygen. As used herein, “substantially free” means that there is less than or equal to about 5%, including less than or equal to about 4%, less than or equal to about 3%, less than or equal to about 2%, less than or equal to about 1%, or less than or equal to about 0.5% of oxygen, on an atomic basis, in the TMDC film. It is thought that the TMDC film that is formed without producing oxygen as a byproduct, thus advantageously minimizing the potential to etch/corrode underlying metal layers.

At operation 122, the processing chamber or substrate surface is optionally purged to remove unreacted chalcogenide precursor, reaction products, and by products.

At decision 130, the method 100 includes determining whether the thickness of the TMDC film, and/or number of cycles of the deposition process cycles 110 has been reached. If the TMDC film has reached a predetermined thickness or a predetermined number of cycles have been performed, the method 100 moves to an optional post-processing operation 140. If the thickness of the TMDC film or the number of cycles has not reached the predetermined threshold, the method 100 returns to the beginning of the deposition process cycle 110 to form additional TMDC film.

In one or more embodiments, the method 100 further comprises repeating forming the transition metal oxide film in the first phase 112 and converting the transition metal oxide film to form a TMDC film in the second phase 120 with a final thickness of greater than or equal to 200 Å. In one or more embodiments, the TMDC film has a final thickness of greater than or equal to 150 Å, greater than or equal to 100 Å, or greater than or equal to 50 Å. In some embodiments, the TMDC film has a final thickness in a range of from 5 Å to 10 Å.

The optional post-processing operation 140 can be any suitable semiconductor manufacturing process known to the skilled artisan such as, for example, a process to modify film properties (e.g., annealing) or a further film deposition process (e.g., additional ALD or CVD processes) to grow additional films.

Advantageously, the transition metal oxide film can be deposited on the substrate surface (first phase 112) and the transition metal oxide film can be converted to the TMDC film (second phase 120) in situ or ex situ.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

The method 100 can be performed at any suitable temperature depending on, for example, the transition metal precursor, oxidant, chalcogenide precursor, or thermal budget of the device. In one or more embodiments, the use of high temperature processing may be undesirable for temperature-sensitive substrates, such as logic devices. In one or more embodiments, the substrate surface is maintained at a temperature in a range of about 150° C. to about 500° C., in a range of about 150° C. to about 450° C., or in a range of about 300° C. to about 450° C. during the entirety of the method 100.

In some embodiments, exposure to the transition metal precursor (operation 113) occurs at a different temperature than the exposure to the oxidant (operation 115) or the chalcogenide precursor (operation 121). In some embodiments, the substrate is maintained at a first temperature in a range of about 150° C. to about 300° C. for the exposure to the transition metal precursor and/or the oxidant, and at a second temperature in the range of about 300° C. to about 500° C. for the exposure to the chalcogenide precursor. In some embodiments, both the transition metal precursor and the chalcogenide precursor are delivered at the same substrate temperature.

According to one or more embodiments, the substrate is subjected to processing prior to and/or after forming the TMDC film. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiment, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiment, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiment, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single semiconductor processing chamber, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiment, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition by minimizing the effect of, for example, local variability in gas flow geometries.

Referring now to FIG. 2, a substrate 200 including a base material 210 having at least one feature 220 formed from a material 230 is shown. The surfaces of the base material 210 and the material 230 form the substrate surface. In some embodiments, the base material 210 and the material 230 are the same. In some embodiments, the base material 210 is a metal or other conductive material. In some embodiments, the material 230 is a dielectric material.

The Figures show a substrate 200 having three features for illustrative purposes; however, those skilled in the art will understand that there can be more or fewer than three features. In one or more embodiments, the substrate 200 comprises at least one feature 220.

The feature 220 may define any suitable shape including, but not limited to, trenches and cylindrical vias. As used in this regard, the term “feature” means any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the height/depth to the width). In some embodiments, the aspect ratio is greater than or equal to about 5:1, 10:1, 15:1, 20:1, 25:1, 30:1, 35:1 or 40:1. In one or more embodiments, the aspect ratio is greater than or equal to about 10:1.

In one or more embodiments, the at least one feature 220 is a trench. In one or more embodiments, the at least one feature 220 comprises a dielectric material and a conductive material. In one or more embodiments, a transition metal oxide film forms selectively on the dielectric material (not shown).

Referring now to FIG. 3, each of the at least one feature 220 shown in FIG. 2 has a transition metal dichalcogenide (TMDC) film 240 deposited thereon. The TMDC film 240 is deposited on or directly on the at least one feature 220. In one or more embodiments, the TMDC film 240 is the TMDC film formed by the method 100 shown in FIG. 1.

In one or more embodiments, the TMDC film 240 is conformally deposited on the at least one feature 220. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

In FIGS. 2 and 3, the substrate 200 having three features 220 has a gap between each of the features 220. Gap fill processes are integral to several semiconductor manufacturing processes. A gap fill process can be used to fill a gap (or feature) with an insulating or conducting material. For example, shallow trench isolation, inter-metal dielectric layers, passivation layers, dummy gate, are all typically implemented by gap fill processes.

In one or more embodiments, the substrate 200 includes a metal fill 250 that is deposited on the TMDC film 240 to fill the gaps between each of the features 220. In one or more embodiments, the metal fill 250 comprises a high-conductivity metal. In some embodiments, the metal fill 250 comprises one or more of copper (Cu), cobalt (Co), tungsten (W), molybdenum (Mo), or ruthenium (Ru).

In some embodiments, the metal fill 250 is substantially free of seams and/or voids. As used in this regard, “substantially free” means that less than about 5%, including less than about 4%, less than about 3%, less than about 2%, less than about 1%, less than about 0.5%, and less than about 0.1% of the total composition of the metal fill 250 on an atomic basis, comprises seams and/or voids.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiment” or “an embodiment” means that a particular feature, structure, material, or characteristic described in connection with the embodiment is included in at least one embodiment of the disclosure. Thus, the appearances of the phrases such as “in one or more embodiment,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A transition metal dichalcogenide (TMDC) film was formed by depositing a transition metal oxide film on a substrate surface by sequentially exposing the substrate surface to a transition metal precursor and an oxidant, and converting the transition metal oxide film to the TMDC film. The transition metal precursor used includes bis(t-butylimino) bis(dimethylamino) tungsten(VI). The oxidants used include oxygen (O₂), O₂ plasma, and ozone (O₃), which may be referred to as “strong” oxidants. The substrate surface was purged after each exposure to remove unreacted transition metal precursor and oxidant, and byproducts. The substrate surface was maintained at a temperature of about 350° C. throughout the process. In specific experiments where the TMDC film was formed on a low-κ dielectric substrate surface, it was found that this process lowers the carbon (C) content of the low-κ dielectric substrate surface, resulting in a greater κ-value (from 2.7 to 3.3) and damage to the low-κ dielectric substrate surface. Accordingly, the TMDC film formed by the process was found to not be compatible for deposition on low-κ dielectric substrate surfaces.

### Inventive Example 1

A process following the operations of method 100 was performed to form a transition metal dichalcogenide (TMDC) film. The process included pre-treating a substrate surface, depositing a transition metal oxide film on the substrate surface by sequentially exposing the substrate surface to a transition metal precursor and an oxidant, and converting the transition metal oxide film to the TMDC film. The transition metal precursor used includes bis(t-butylimino) bis(dimethylamino) tungsten(VI). The oxidants used include one or more of an alcohol or deionized/deoxygenated water, which may be referred to as “mild” oxidants. In one or more experiments, isopropyl alcohol was used as the oxidant. The substrate surface was purged after each exposure to reacted transition metal precursor and oxidant and byproducts. The substrate surface was maintained at a temperature of about 350° C. throughout the process.

As described herein and with respect to Conventional Example 1, it has been observed that the substrate surface, such as, for example, a low-κ dielectric substrate surface, is sensitive to strong oxidants while growing the transition metal oxide film. It remains a challenge for the transition metal precursors to adsorb on inherently highly hydrophobic alkyl-group terminated dielectric surfaces. The process of Inventive Example 1, as in method 100, comprises pre-treating the substrate surface at operation comprises a plasma treatment or ultraviolet (UV) radiation exposure to remove surface alkyl groups and make the low-κ dielectric surface suitable for precursor adsorption. Advantageously, the oxidant comprising one or more of an alcohol or deionized/deoxygenated water does not damage the low-κ dielectric surface. Additionally, use of the transition metal precursors and the oxidant comprising one or more of an alcohol or deionized/deoxygenated water advantageously enables uniform growth of the transition metal oxide film without modifying the properties of, or damaging the low-κ dielectric surface.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a transition metal dichalcogenide film, the method comprising:
depositing a transition metal oxide film on a semiconductor substrate surface by sequentially exposing the semiconductor substrate surface to a transition metal precursor and an oxidant, the oxidant comprising one or more of an alcohol or deionized/deoxygenated water; and
converting the transition metal oxide film to the transition metal dichalcogenide film.

2. The method of claim 1, further comprising pre-treating the semiconductor substrate surface prior to depositing the transition metal oxide film.

3. The method of claim 2, wherein pre-treating the semiconductor substrate surface comprises a plasma treatment or ultraviolet (UV) radiation exposure.

4. The method of claim 1, wherein the semiconductor substrate surface is maintained at a temperature in a range of about 150° C. to about 450° C.

5. The method of claim 1, wherein the semiconductor substrate surface comprises a dielectric material.

6. The method of claim 1, wherein the semiconductor substrate surface comprises at least one feature with an aspect ratio greater than or equal to about 10:1.

7. The method of claim 1, wherein depositing the transition metal oxide film comprises directly forming the transition metal oxide film without forming a transition metal film intermediate.

8. The method of claim 1, wherein the transition metal precursor does not comprise oxygen or halogen atoms.

9. The method of claim 1, wherein the transition metal precursor comprises one or more of bis(t-butylimino) bis(dimethylamino) tungsten(VI), bis(isopropylcyclopentadienyl) tungsten(IV) dihydride, bis(cyclopentadienyl) tungsten dihydride, bis(t-butylimino) bis(dimethylamino) molybdenum(VI), pentakis (dimethylamino) tantalum (V), or tetrakis (dimethylamido) titanium (IV).

10. The method of claim 1, further comprising purging the semiconductor substrate surface of the transition metal precursor and the oxidant prior to converting the transition metal oxide film.

11. The method of claim 1, wherein converting the transition metal oxide film is performed at a pressure in a range of from 0.1 Torr to 100 Torr.

12. The method of claim 1, wherein converting the transition metal oxide film to the transition metal dichalcogenide film comprises exposing the transition metal oxide film to a chalcogenide precursor.

13. The method of claim 1, wherein the transition metal dichalcogenide film is substantially free of oxygen.

14. The method of claim 6, wherein the semiconductor substrate surface comprises the at least one feature and the transition metal dichalcogenide film is conformally deposited on the at least one feature.

15. The method of claim 1, wherein depositing the transition metal oxide film on the semiconductor substrate surface and converting the transition metal oxide film to the transition metal dichalcogenide film are performed in a single semiconductor processing chamber.

16. A method of forming a transition metal dichalcogenide film on a semiconductor substrate surface comprising at least one feature, the method comprising:
sequentially exposing the semiconductor substrate surface to a transition metal precursor and an oxidant to directly deposit a transition metal oxide film without forming a transition metal film intermediate, the transition metal precursor comprising one or more of bis(t-butylimino) bis(dimethylamino) tungsten(VI), bis(isopropylcyclopentadienyl) tungsten(IV) dihydride, bis(cyclopentadienyl) tungsten dihydride, bis(t-butylimino) bis(dimethylamino) molybdenum(VI), pentakis (dimethylamino) tantalum (V), or tetrakis (dimethylamido) titanium (IV) and the oxidant comprising one or more of an alcohol or deionized/deoxygenated water; and
exposing the transition metal oxide film to a chalcogenide precursor to convert the transition metal oxide film to the transition metal dichalcogenide film,
wherein the semiconductor substrate surface is maintained at a temperature in a range of about 150° C. to about 450° C. and converting the transition metal oxide film is performed at a pressure in a range of from 0.1 Torr to 100 Torr.

17. The method of claim 16, further comprising pre-treating the semiconductor substrate surface prior to depositing the transition metal oxide film.

18. The method of claim 17, wherein pre-treating the semiconductor substrate surface comprises a plasma treatment or ultraviolet (UV) radiation exposure.

19. The method of claim 16, further comprising purging the semiconductor substrate surface of the transition metal precursor and the oxidant prior to converting the transition metal oxide film.

20. The method of claim 16, wherein depositing the transition metal oxide film on the semiconductor substrate surface and converting the transition metal oxide film to the transition metal dichalcogenide film are performed in a single semiconductor processing chamber.
